(19) United States
(12) Patent Application Publication
(10) Pub. No.: US 2026/0114008 A1
(43) Pub. Date: Apr. 23, 2026

(54) SEMICONDUCTOR DEVICE AND METHOD OF MANUFACTURING THE SAME

(71) Applicant: TAIWAN SEMICONDUCTOR MANUFACTURING COMPANY LTD., HSINCHU (TW)

(72) Inventors: YI-HUAN CHEN, HSINCHU CITY (TW); JHU-MIN SONG, NANTOU COUNTY (TW); CHIA-JUI LEE, HSINCHU COUNTY (TW); FEI-YUN CHEN, HSINCHU (TW)

(21) Appl. No.: 18/923,742

(22) Filed: Oct. 23, 2024

(51) Int. Cl. H01L 29/66; H01L 21/762; H01L 29/423

(52) U.S. Cl. CPC H10D 64/017; H10D 30/6891; H10W 10/014; H10W 10/17

(57) ABSTRACT

A semiconductor device and a method of manufacturing the same are provided. The semiconductor device includes a substrate, a gate electrode, a first doped region, a second doped region, and a dummy gate electrode. The gate electrode is disposed on the substrate. The first doped region and the second doped region are disposed on two sides of the gate electrode. The dummy gate electrode is disposed on the substrate and between the gate electrode and the second doped region.

### BACKGROUND

Currently, semiconductor devices are widely used in various fields, such as cloud storage, medicine, transportation, mobile devices, etc. Current trends in semiconductor device manufacturing focus on providing semiconductor devices with smaller dimensions and better power efficiency. It is therefore desirable to continuously improve the structure and manufacturing of semiconductor devices.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1 is a cross-sectional view of a semiconductor device in accordance with some embodiments.

FIG. 2A is a cross-sectional view of a semiconductor device in accordance with some embodiments.

FIG. 2B illustrates a layout of the semiconductor device of FIG. 2A in accordance with some embodiments.

FIG. 3 is a cross-sectional view of a semiconductor device in accordance with some embodiments.

FIG. 4 is a cross-sectional view of a semiconductor device in accordance with some embodiments.

FIG. 5A, FIG. 5B, FIG. 5C, FIG. 5D, FIG. 5E, FIG. 5F, FIG. 5G, FIG. 5H, FIG. 5I, and FIG. 5J illustrate various stages of manufacturing a semiconductor device, in accordance with some embodiments of the present disclosure.

FIG. 6 is a flow chart illustrating a method for manufacturing a semiconductor device according to various aspects of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

The present disclosure generally relates to semiconductor devices, and more particularly to semiconductor devices with a dummy gate electrode abutting one of the source/drain features. The dummy gate electrode can be configured to improve the surface roughness of an intermediate structure, which can also improve the flatness of subsequent layers. The performance of the semiconductor device can thus be enhanced. The semiconductor device of the disclosure can be applied to a planar device, a fin field-effect transistor (FinFET) device, a nano-sheet transistor device, a complementary field-effect transistor (CFET) device, or other devices.

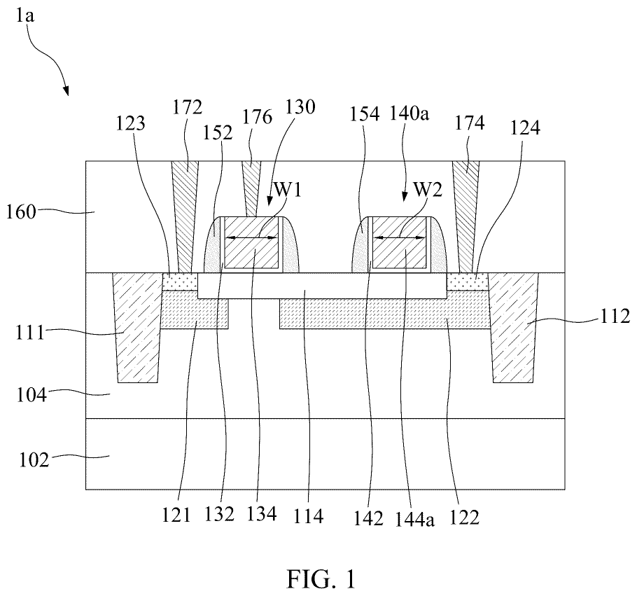

FIG. 1 illustrates a cross-sectional view of a semiconductor device 1a, in accordance with some embodiments of the present disclosure.

In some embodiments, the semiconductor device 1a includes a substrate 102. The substrate 102 includes a semiconductor substrate, such as a bulk semiconductor, a semiconductor-on-insulator (SOI) substrate, or the like, which may be doped (e.g., with a p type or an n type dopant) or undoped. The substrate 102 may include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; any other suitable material; or a combination thereof. In some embodiments, the alloy semiconductor substrate includes a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy can be mechanically strained by another material in contact with the SiGe alloy. In some embodiments, the substrate 102 may have a multilayer structure, or the substrate 102 may include a multilayer compound semiconductor structure.

The semiconductor device 1a includes a well region 104. The well region 104 is formed within or on the substrate 102. In some embodiments, the well region 104 is doped with an n type dopant such as phosphorus (P), arsenic (As), or antimony (Sb). In some other embodiments, the well region 104 is doped with a p type dopant such as boron (B) or indium (In). In some embodiments, the well region 104 may have a higher doping concentration than the substrate 102. In some embodiments, the well region 104 includes a substantially constant doping concentration. In some embodiments, the well region 104 includes a step, gradient, or other doping profile. For example, the well region 104 may include a gradually changing doping concentration.

In some embodiments, the semiconductor device 1a includes isolation regions 111 and 112. The isolation regions 111 and 112 are formed within the well region 104. The isolation regions 111 and 112 are recessed from the upper surface of the substrate 102. In some embodiments, the isolation regions 111 and 112 have a ring-shaped profile surrounding the active region (e.g., the region configured to define a transistor) from a top view. The isolation regions 111 and 112 may be used for electrically isolating the semiconductor device 1a from another device. The isolation regions 111 and 112 may be used for physically isolating the semiconductor device 1a from another semiconductor device. Each of the isolation regions 111 and 112 may include a shallow trench isolation (STI). In some embodiments, the isolation regions 111 and 112 may include, for example, silicon oxide (SiO₂), silicon nitride (Si₃N₄), silicon oxynitride, silicon nitride oxide, a high-k material or combinations thereof.

In some embodiments, the semiconductor device 1a includes an insulating structure 114. In some embodiments, the insulating structure 114 abuts the upper surface of the substrate 102. In some embodiments, the insulating structure 114 is formed within the well region 104. In some embodiments, the insulating structure 114 includes local oxidation of silicon (LOCOS). In some embodiments, the insulating structure 114 can function as a gate dielectric. In some embodiments, the insulating structure 114 is configured to reduce the parasitic capacitor of the semiconductor device 1a, thereby potentially improving the operation lag or RC delay of the semiconductor device 1a. In some embodiments, the insulating structure 114 may include, for example, silicon oxide (SiO₂) or other suitable materials.

In some embodiments, the semiconductor device 1a includes doped regions 121 and 122. The doped regions 121 and 122 are formed within the well region 104. The doped regions 121 and 122 are surrounded by the isolation regions 111 and 112. In some embodiments, each of the doped regions 121 and 122 is in contact with the lower surface and the lateral surface of the insulating structure 114. The doped regions 121 and 122 are surrounded by the well region 104. In some embodiments, each of the doped regions 121 and 122 has a doping concentration greater than that of the well region 104. The doped regions 121 and 122 could include a lightly doped source (LDS) or lightly doped drain (LDD). The doped regions 121 and 122 may be doped with an n type dopant such as phosphorus (P), arsenic (As), or antimony (Sb). In some other embodiments, the well region 104 may be doped with a p type dopant such as boron (B) or indium (In). In some embodiments, the doped regions 121 and 122 may include a substantially constant doping concentration. In some embodiments, the doped regions 121 and 122 may include a step, gradient, or other doping profile. For example, the doped regions 121 and 122 may include a gradually changing doping concentration.

In some embodiments, the semiconductor device 1a includes doped regions 123 and 124. The doped regions 123 and 124 may be formed within at least a portion of the doped regions 121 and 122. The doped regions 123 and 124 may contact at least a portion of the isolation regions 111 and 112. Each of the doped regions 123 and 124 may contact the lateral surface of the insulating structure 114. In some embodiments, the doped region 123 (or 124) may have a different doping concentration than that of the doped regions 121 (or 122). In some embodiments, the doped regions 123 and 124 may have a doping concentration greater than that of the doped regions 121 and 122. The doped regions 123 and 124 can function as a source/drain feature of a device. In some embodiments, the doped region 123 can be referred to as a source feature, and the doped region 124 can be referred to as a drain feature. However, the present disclosure is not intended to be limiting. In this disclosure, Source/drain feature(s) may refer to a source or a drain, individually or collectively dependent upon the context. The doped regions 123 and 124 may be doped with an n type dopant such as phosphorus (P), arsenic (As), or antimony (Sb). In some other embodiments, the well region 104 may be doped with a p type dopant such as boron (B) or indium (In). In some embodiments, the doped regions 123 and 124 may include a substantially constant doping concentration. In some embodiments, the doped regions 123 and 124 may include a step, gradient, or other doping profile. For example, the doped regions 123 and 124 may include a gradually changing doping concentration.

In some embodiments, the semiconductor device 1a includes a gate structure 130. In some embodiments, the gate structure 130 is disposed on or over the substrate 102. In some embodiments, the gate structure 130 is disposed on or over the insulating structure 114. In some embodiments, the doped regions 123 and 124 are disposed on two different sides of the gate structure 130. In some embodiments, the gate structure 130 is spaced apart from the substrate 102 by the insulating structure 114. In some embodiments, the distance between one of the source/drain features and the gate structure 130 is different from the distance between the other one of the source/drain features and the gate structure 130. For example, the distance between the doped region 123 (or a source feature) and the gate structure 130 may be less than the distance between the doped region 124 (or a drain feature) and the gate structure 130. As a result, the semiconductor device 1a can sustain a higher voltage.

The gate structure 130 includes a gate dielectric 132 and a gate electrode 134. In some embodiments, the gate dielectric 132 defines a recess accommodating the gate electrode 134. The gate dielectric 132 may have a single layer or a multi-layer structure. In some embodiments, the gate dielectric 132 is a multi-layer structure that includes an interfacial layer and a high-k (dielectric constant greater than 4) dielectric layer. The interfacial layer can include dielectric material such as silicon oxide, silicon nitride, silicon oxynitride, other dielectric material, or a combination thereof. The high-k dielectric layer can include high-k dielectric material, such as hafnium oxide (HfO₂), silicon doped hafnium oxide (HSO), lanthanum oxide (La₂O₃), lanthanum aluminum oxide (LaAlO₃), zirconium oxide (ZrO₂), zirconium orthosilicate (ZrSiO₄), aluminum oxide (Al₂O₃), or other suitable materials. In some embodiments, the high-k dielectric material can further be selected from metal oxides, metal nitrides, metal silicates, transition metal-oxides, transition metal-nitrides, transition-metal silicates, metal oxynitrides, metal aluminates, and combinations thereof.

The gate electrode 134 is disposed on the gate dielectric 132. In some embodiments, the lateral surface and the lower surface of the gate electrode 134 are in contact with the gate dielectric 132. In some embodiments, the gate electrode 134 includes at least one metallic material including elements and compounds such as, molybdenum (Mo), copper (Cu), tungsten (W), titanium (Ti), tantalum (Ta), titanium nitride (TiN), tantalum nitride (TaN), nickel silicide (NaSi), cobalt silicide (CoSi), or other suitable conductive materials. In some embodiments, the gate electrode 134 includes a work function metal layer that provides a metal gate with an n type-metal work function or p type-metal work function. The p type-metal work function materials include materials such as ruthenium, palladium, platinum, cobalt, nickel, conductive metal oxide, or other suitable materials. The n type-metal work function materials include materials such as hafnium zirconium, titanium, tantalum, aluminum, metal carbides (e.g., hafnium carbide, zirconium carbide, titanium carbide, and aluminum carbide), aluminides, or other suitable materials.

In some embodiments, the semiconductor device 1a includes a dummy gate structure 140a. In some embodiments, the dummy gate structure 140a is disposed on or over the substrate 102. In some embodiments, the dummy gate structure 140a is disposed on or over the insulating structure 114. In some embodiments, the dummy gate structure 140a is spaced apart from the substrate 102 by the insulating structure 114. In some embodiments, the gate structure 130 is closer to one of the source/drain features, and the dummy gate structure 140a is closer to one of the other source/drain features. For example, the gate structure 130 may be closer to the doped region 123 (or a source feature), and the dummy gate structure 140a may be closer to the doped region 124 (or a drain feature). In some embodiments, the gate structure 130, the doped regions 123 and 124 can define a transistor.

In some embodiments, the structure and the composition of the dummy gate structure 140a are the same as or similar to those of the gate structure 130. In some embodiments, the dummy gate structure 140a includes a dummy gate dielectric 142 and a dummy gate electrode 144a. In some embodiments, the dummy gate dielectric 142 defines a recess accommodating the dummy gate electrode 144a. The dummy gate dielectric 142 may have a single layer or a multi-layer structure. In some embodiments, the dummy gate dielectric 142 is a multi-layer structure that includes an interfacial layer and a high-k (dielectric constant greater than 4) dielectric layer. The interfacial layer can include dielectric material such as silicon oxide, silicon nitride, silicon oxynitride, other dielectric material, or a combination thereof. The high-k dielectric layer can include high-k dielectric material, such as hafnium oxide (HfO₂), silicon doped hafnium oxide (HSO), lanthanum oxide (La₂O₃), lanthanum aluminum oxide (LaAlO₃), zirconium oxide (ZrO₂), zirconium orthosilicate (ZrSiO₄), aluminum oxide (Al₂O₃), or other suitable materials. In some embodiments, the high-k dielectric material can further be selected from metal oxides, metal nitrides, metal silicates, transition metal-oxides, transition metal-nitrides, transition-metal silicates, metal oxynitrides, metal aluminates, and combinations thereof.

The dummy gate electrode 144a is disposed on the dummy gate dielectric 142. In some embodiments, the dummy gate electrode 144a vertically overlaps the insulating structure 114. In some embodiments, the dummy gate electrode 144a vertically overlaps the doped region 122. In some embodiments, the material of the dummy gate electrode 144a may be the same as or similar to that of the gate electrode 134. For example, the dummy gate electrode 144a may include at least one metallic material including elements and compounds such as molybdenum (Mo), copper (Cu), tungsten (W), titanium (Ti), tantalum (Ta), titanium nitride (TiN), tantalum nitride (TaN), nickel silicide (NaSi), cobalt silicide (CoSi), or other suitable conductive materials. In some embodiments, the dummy gate electrode 144a includes a work function metal layer that provides a metal gate with an n type-metal work function or p type-metal work function. The p type-metal work function materials include materials such as ruthenium, palladium, platinum, cobalt, nickel, conductive metal oxide, or other suitable materials. The n type-metal work function materials include materials such as hafnium zirconium, titanium, tantalum, aluminum, metal carbides (e.g., hafnium carbide, zirconium carbide, titanium carbide, and aluminum carbide), aluminides, or other suitable materials. In some embodiments, the dummy gate electrode 144a is electrically floating. In some embodiments, the dummy gate electrode 144a is electrically isolated from the gate electrode 134.

The gate electrode 134 has a width W1 along an extension direction of the insulating structure 114. The dummy gate electrode 144a has a width W2 along an extension direction of the insulating structure 114. In some embodiments, the width W1 of the gate electrode 134 is substantially the same as the width W2 of the dummy gate electrode 144a.

In some embodiments, the semiconductor device 1a includes a spacer 152 and a spacer 154. The spacer 152 is disposed on sidewalls of the gate dielectric 132. The spacer 154 is disposed on sidewalls of the dummy gate dielectric 142. The spacer 152 is disposed on or over the insulating structure 114 and abut the doped region 123. The spacer 154 is disposed on or over the insulating structure 114 and abuts the doped region 124. In some embodiments, the location of the doped region 123 is defined by the spacer 152 and the isolation region 111. In some embodiments, the location of the doped region 124 is defined by the spacer 154 and the isolation region 112.

Each of the spacers 152 and 154 may include a multi-layered structure. In some embodiments, each of the spacers 152 and 154 includes silicon nitride, silicon oxynitride, silicon oxide, other suitable materials, or a combination thereof.

In some embodiments, the semiconductor device 1a includes a dielectric structure 160. The dielectric structure 160 may include a multi-layered structure. In some embodiments, the dielectric structure 160 may include a dielectric material, such as an oxide-containing material or other suitable materials. The oxide-containing material may include phosphosilicate glass (PSG), tetraethylorthosilicate (TEOS) oxide, un-doped silicate glass, silicon dioxide, doped silicon dioxide such as borophosphosilicate glass (BPSG), fused silica glass (FSG), boron doped silicon glass (BSG), another suitable dielectric material, or a combination thereof. The dielectric structure 160 can also be referred to as an interlayer dielectric (ILD).

In some embodiments, the semiconductor device 1a includes conductive contacts 172, 174, and 176. The conductive contacts 172, 174, and 176 are embedded within the dielectric structure 160. The conductive contact 172 is disposed on and electrically connected to the doped region 123. The conductive contact 174 is disposed on and electrically connected to the doped region 124. The conductive contact 176 is disposed on and electrically connected to the gate electrode 134. The conductive contacts 172, 174, and 176 include one or more conductive materials, such as tungsten, aluminum, copper, titanium, tantalum, titanium nitride, tantalum nitride, alloys thereof, and/or multi-layers thereof.

In the embodiments of the present disclosure, the dummy gate structure 140a is configured to improve the surface roughness of an intermediate structure, which will be described later. When a polishing technique is performed, such as chemical mechanical polishing (CMP), it may cause surface topography over a region with lower rigidity and far from materials with greater rigidity. In some cases, when the distance between the source/drain feature and the gate structure is enlarged so that the device can tolerate a higher voltage, there may be greater undulation of the dielectric layer (e.g., one of the layers of the dielectric structure 160) over the source/drain features after a polishing technique is performed, negatively impacting the flatness of subsequent layers and degrading semiconductor device performance. In this embodiment, placing dummy gate structure 140a between gate structure 130 and conductive contact 174 (or doped region 124) can reduce the undulation of the dielectric layers of dielectric structure 160 in the region adjacent to doped region 124, thereby addressing the aforementioned issues.

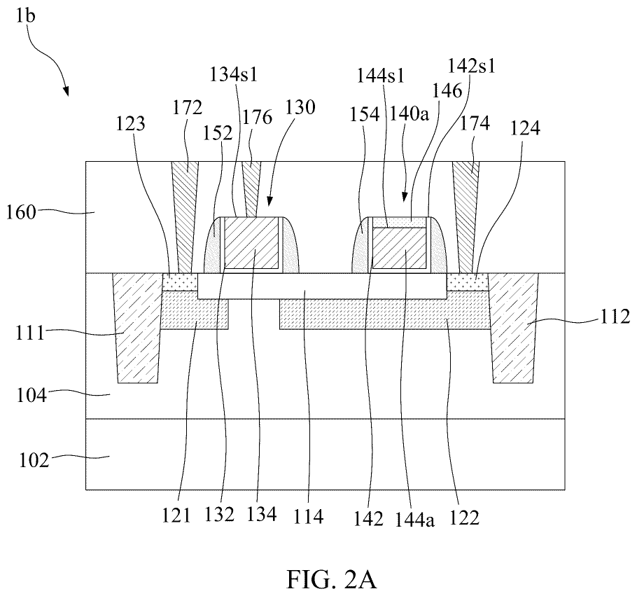

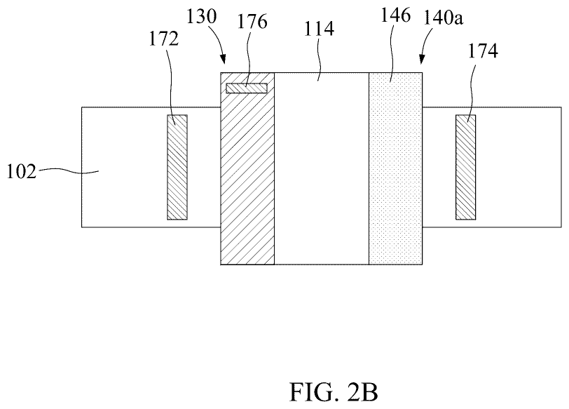

FIG. 2A and FIG. 2B illustrate a semiconductor device 1b in accordance with some embodiments, wherein FIG. 2A is a cross-sectional view, and FIG. 2B illustrates a layout of FIG. 2A. In some embodiments, the semiconductor device 1b has a structure similar to that of the semiconductor device 1a, and one of the differences between them is that the semiconductor device 1b includes a cap layer 146.

In some embodiments, the cap layer 146 is disposed on or over the dummy gate structure 140a. In some embodiments, the cap layer 146 is surrounded by the dummy gate dielectric 142. In some embodiments, the cap layer 146 cover a surface 144s1 (or upper surface) of the dummy gate electrode 144a. In some embodiments, the cap layer 146 is configured to prevent the coupling between the dummy gate structure 140a and the source/drain features (e.g., the doped region 124). In some embodiments, the cap layer 146 includes silicon nitride, silicon oxynitride, silicon carbide, or other suitable materials. In some embodiments, a surface 134s1 (or upper surface) of the gate electrode 134 is located at an elevation, with respect to the upper surface of the substrate 102, different from that of the surface 144s1 of the dummy gate electrode 144a. In some embodiments, the elevation of the surface 134s1 of the gate electrode 134 is higher than the elevation of the surface 144s1 of the dummy gate electrode 144a with respect to the upper surface of the substrate 102. In some embodiments, the surface 144s1 of the dummy gate electrode 144a is recessed from a surface 142s1 (or upper surface) of the dummy gate dielectric 142.

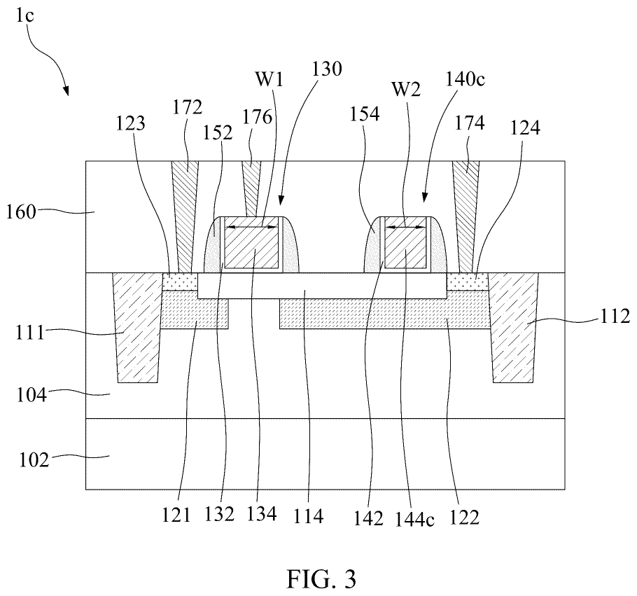

FIG. 3 is a cross-sectional view of a semiconductor device 1c in accordance with some embodiments. In some embodiments, the semiconductor device 1c has a structure similar to that of the semiconductor device 1c, and one of the differences between them is that the semiconductor device 1c includes a dummy gate structure 140c.

In some embodiments, the width of the dummy gate structure 140c is different from the width of the gate structure 130. For example, the width W1 of the gate electrode 134 is different from the width W2 of the dummy gate electrode 144c. Since the dummy gate structure 140c does not provide the function of electrically coupling, the dimension of the dummy gate electrode 144c can depend on the requirements of the design.

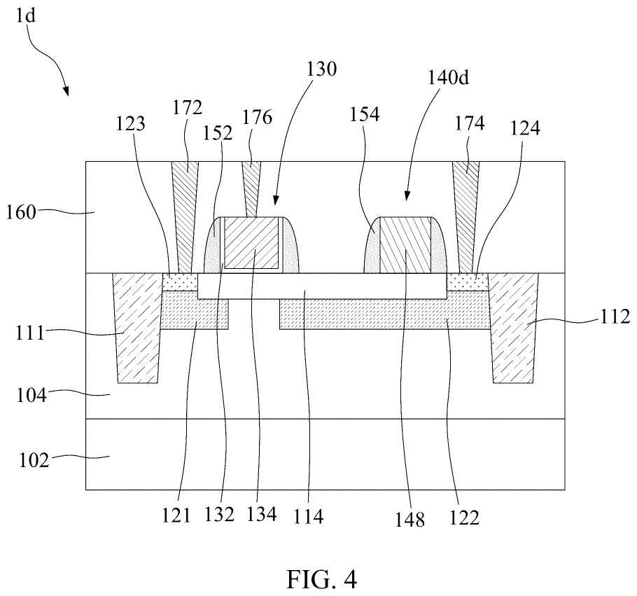

FIG. 4 is a cross-sectional view of a semiconductor device 1d in accordance with some embodiments. In some embodiments, the semiconductor device 1d has a structure similar to that of the semiconductor device 1a, and one of the differences between them is that the semiconductor device 1d includes a dummy gate structure 140d.

In some embodiments, the composition of the dummy gate structure 140d is different from that of the gate structure 130. In some embodiments, the structure of the dummy gate structure 140d is different from that of the gate structure 130. In some embodiments, the dummy gate structure 140d includes a dummy gate electrode 148. In some embodiments, the dummy gate electrode 148 is in contact with the insulating structure 114. In some embodiments, the dummy gate electrode 148 includes a material with a rigidity (or hardness) greater than that of the dielectric structure 160. In some embodiments, the dummy gate electrode 148 includes polysilicon, silicon germanium, or other suitable materials.

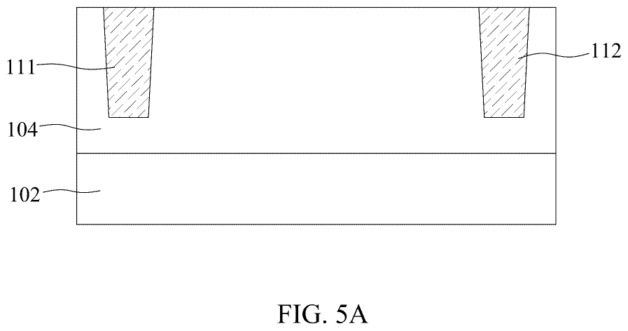

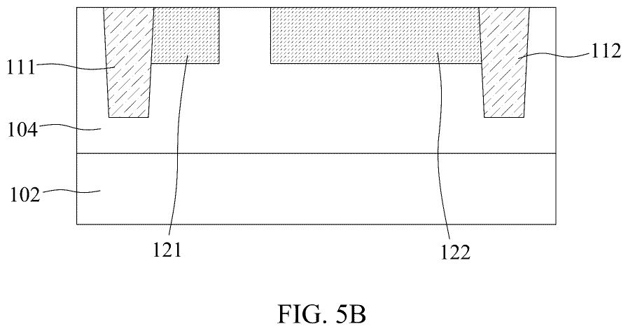

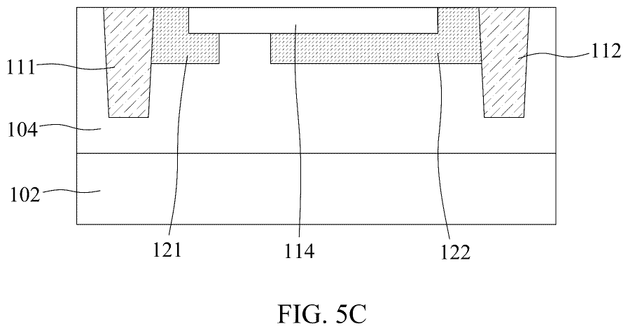

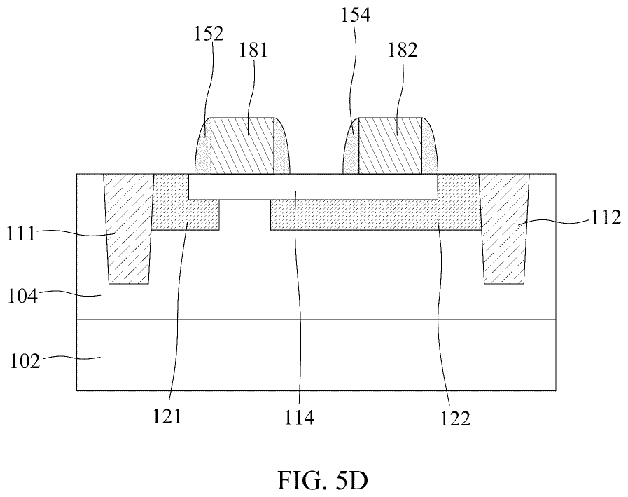

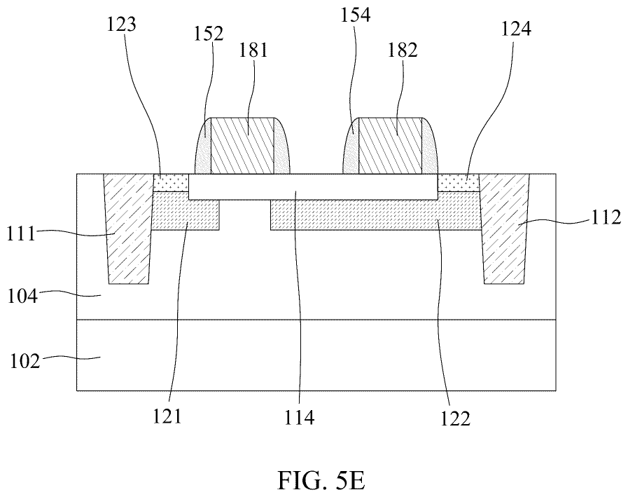

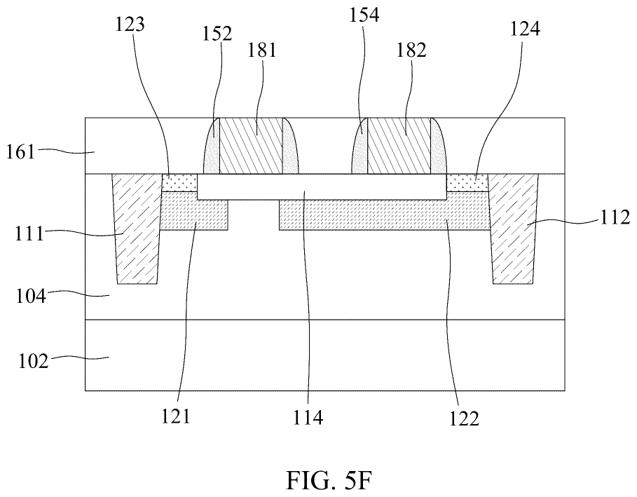

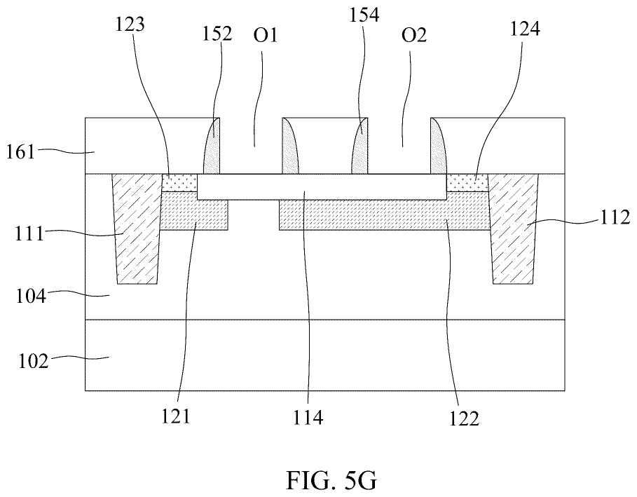

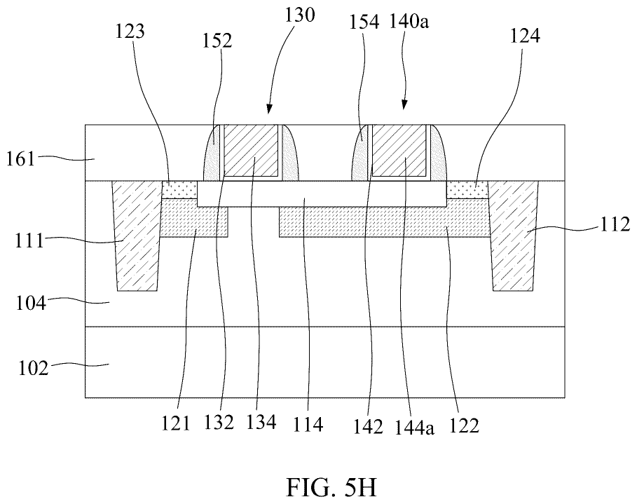

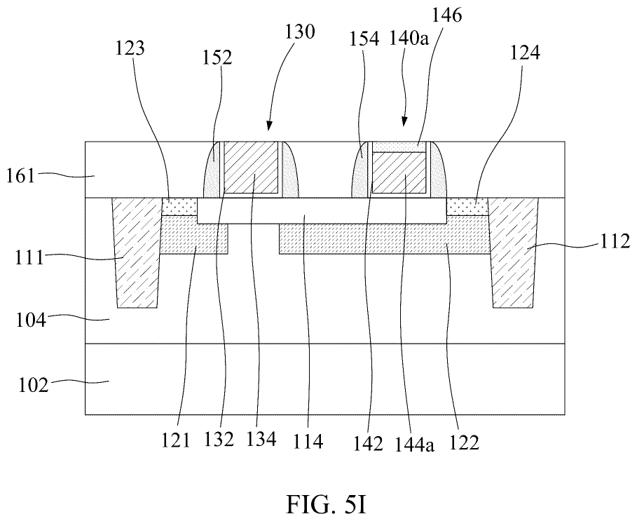

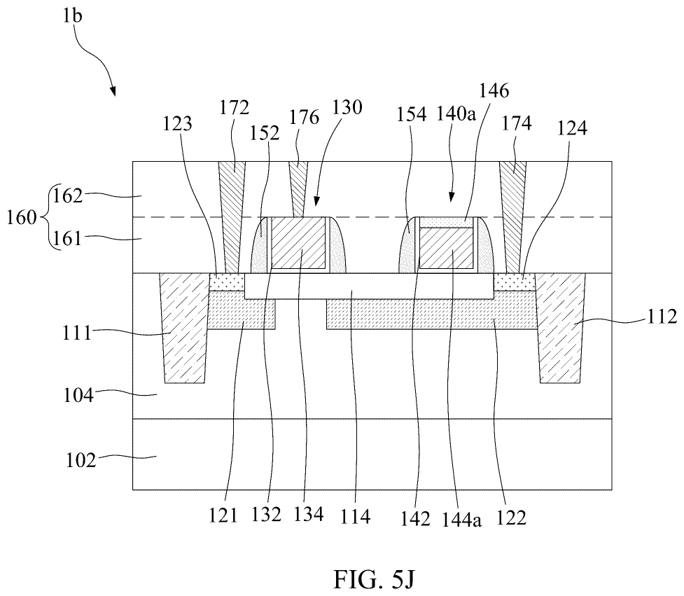

FIG. 5A to FIG. 5J illustrate various stages of manufacturing a semiconductor device, in accordance with some embodiments of the present disclosure.

Referring to FIG. 5A, the substrate 102 is provided. The well region 104 is formed with the substrate 102 by an implantation technique. The isolation regions 111 and 112 are formed within the substrate 102. In some embodiments, portions of the substrate 102 are removed to form trenches. A dielectric material(s) is formed to fill the trenches, which thereby produces the isolation regions 111 and 112. In some embodiments, the dielectric material(s) is formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. The filled trenches may each have a multi-layer structure such as a thermal oxide liner layer filled with silicon nitride or silicon oxide. In general, the isolation regions 111 and 112 may be formed using a processing sequence such as: growing a pad oxide, forming a low pressure chemical vapor deposition (LPCVD) nitride layer, patterning an STI opening using photoresist and masking, etching a trench in the substrate, optionally growing a thermal oxide trench liner to improve the trench interface, filling the trench with CVD oxide, using chemical mechanical polishing (CMP) processing to etch back and planarize, and using a nitride stripping process to remove the silicon nitride.

Referring to FIG. 5B, the doped regions 121 and 122 are formed within the well region 104. In some embodiments, a mask is formed to cover the substrate 102 and expose the region where the doped regions 121 and 122 are formed. The doped region 121 is formed adjacent to the isolation region 111, and the doped region 122 is formed adjacent to the isolation region 112.

Referring to FIG. 5C, the insulating structure 114 is formed within the substrate 102. In some embodiments, a portion of the substrate 102 is removed by an etching technique (e.g., dry etching or wet etching), and the insulating structure 114 may be formed by thermal oxidation of the substrate 102 or other suitable techniques. The insulating structure 114 can vertically and laterally expand a certain thickness and distance, respectively. Although FIG. 5C illustrates that the insulating structure 114 is a flat layer, the insulating structure 114 may have a bird's beak profile at its lateral tip.

Referring to FIG. 5D, a sacrifice gate 181 and a sacrifice gate 182 are formed over the insulating structure 114. The sacrifice gate 182 is spaced apart from the sacrifice gate 181. In some embodiments, the sacrifice gate 181 and sacrifice gate 182 are formed by a deposition technique, such as chemical vapor deposition (CVD), physical vapor deposition (PVD), atomic layer deposition (ALD), and other suitable techniques. The spacer 152 is formed on sidewalls of the sacrifice gate 181. The spacer 154 is formed on sidewalls of the sacrifice gate 182. Each of the spacers 152 and 154 is formed by, for example, CVD, ALD, LPCVD, or other suitable techniques.

Referring to FIG. 5E, the doped region 123 is formed on the doped region 121. The doped region 124 is formed on the doped region 122. In some embodiments, the spacer 152 and the isolation region 111 can be configured to determine the location of the doped region 123. In some embodiments, the spacer 154 and the isolation region 112 can be configured to determine the location of the doped region 124. In some embodiments, the doped region 123 abuts the sacrifice gate 181. In some embodiments, the doped region 124 abuts the sacrifice gate 182. In some embodiments, the doped regions 123 and 124 are formed by doping impurities into the substrate 102, and the spacers 152 and 154 can function as a mask to define the locations of the doped regions 123 and 124.

Referring to FIG. 5F, a dielectric layer 161 is formed to cover the substrate 102, the isolation region 111, and the isolation region 112. In some embodiments, the dielectric layer 161 is formed by CVD, plasma enhanced CVD (PECVD), flowable CVD (FCVD), ALD, or other suitable techniques. In some embodiments, a dielectric material(s) is deposited to cover the sacrifice gate 181 and the sacrifice gate 182. Next, a polishing technique (e.g., CMP) is performed to planarize the upper surfaces of the dielectric layer 161, the sacrifice gate 181, and the sacrifice gate 182.

Referring to FIG. 5G, the sacrifice gate 181 and the sacrifice gate 182 are removed to expose the insulating structure 114. Openings O1 and O2 are formed to expose the insulating structure 114.

Referring to FIG. 5H, the gate dielectric 132 is formed within the opening O1. The dummy gate dielectric 142 is formed within the opening O2. The gate dielectric 132 and dummy gate dielectric 142 are each formed by ALD, CVD, PVD, or other suitable techniques. The gate electrode 134 is formed over the gate dielectric 132 to fill the opening O1. The dummy gate electrode 144a is formed to fill the opening O2. The gate electrode 134 and dummy gate electrode 144a are each formed by PVD, CVD, ALD, or other suitable techniques.

In some embodiments, a gate dielectric material is formed to fill the openings O1 and O2 and cover the upper surface of the dielectric layer 161, and a conductive material is formed to fill the openings O1 and O2 and cover the gate dielectric material. Next, a polishing technique (e.g., CMP) is performed to planarize the upper surfaces of the dielectric layer 161, the gate electrode 134, and the dummy gate electrode 144a. In this embodiment, the formation of the dummy gate electrode 144a can improve the surface roughness of the upper surface of the dielectric layer 161, especially the surface roughness over the doped region 124. In a comparative example where a dummy gate electrode is not formed, a relatively long distance between the gate electrode and the drain feature may cause a poor surface roughness of a dielectric layer (e.g., the ILD) abutting the source/drain feature (e.g., the drain feature), negatively impacting the flatness of subsequent layers and degrading semiconductor device performance. In this embodiment, the dummy gate structure 140a can be configured to reduce the undulation of the dielectric layer 161 abutting the dummy gate electrode 144, addressing aforementioned issues. Further, the processes for producing the dummy gate structure 140a can be integrated with those for producing the gate structure 130, which minimizes the need for additional equipment or specialized processes. As a result, the manufacturing of the dummy gate structure 140a does not pose a significant burden in terms of process complexity or cost.

Referring to FIG. 5I, the cap layer 146 is formed to cover the dummy gate electrode 144a. In some embodiments, an upper portion of the dummy gate electrode 144a is removed to form a recess, and a dielectric material is deposited to fill the recess of the dummy gate electrode 144a. A polishing technique (e.g., CMP) is performed to planarize the upper surfaces of the dielectric layer 161, the gate electrode 134, and the cap layer 146. In some embodiments, the cap layer 146 is formed by CVD, FCVD, PVD, ALD, or other suitable techniques. Although FIG. 5I illustrates that no cap layer is formed over the gate electrode 134, an additional cap layer can be formed on the top of the gate electrode 134 in other embodiments.

Referring to FIG. 5J, a dielectric layer 162 is formed to cover the dielectric layer 161, the gate structure 130, and the dummy gate structure 140a. The dielectric layer 162 is formed by CVD, PECVD, FCVD, ALD, or other suitable techniques. The conductive contacts 172, 174, and 176 are formed over the doped region 123, the doped region 124, and the gate electrode 134, respectively. As a result, a semiconductor device (e.g., the semiconductor device 1b) can be produced.

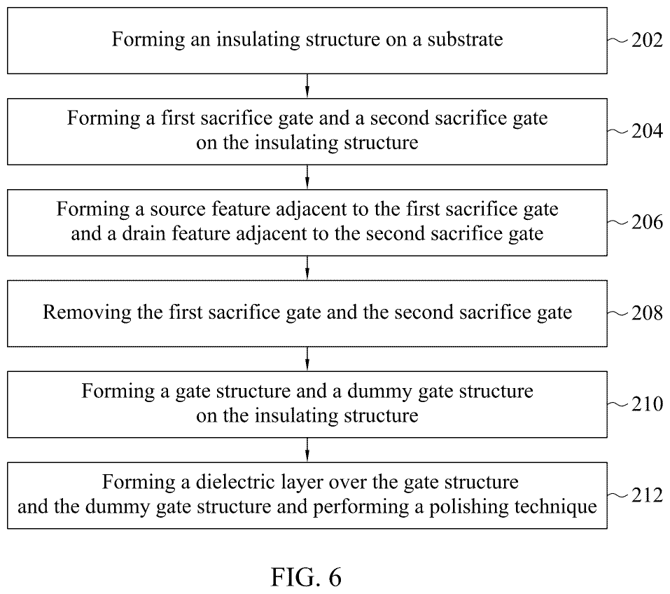

FIG. 6 is a flow chart illustrating a method 2 for manufacturing a semiconductor device (e.g., the semiconductor devices 1a to 1d) according to various aspects of the present disclosure.

The method 2 begins with an operation 202 in which a substrate is formed. An insulating structure is formed on or within the substrate.

The method 2 continues with an operation 204 in which a first sacrifice gate and a second sacrifice gate are formed on the insulating structure.

The method 2 continues with an operation 206 in which a source feature is formed adjacent to the first sacrifice gate and a drain feature is formed adjacent to the second sacrifice gate.

The method 2 continues with an operation 208 in which the first sacrifice gate and the second sacrifice gate are removed to form a first opening and a second opening.

The method 2 continues with an operation 210 in which a gate structure is formed within the first opening and a dummy gate structure is formed within the second opening.

The method 2 continues with an operation 212 in which a dielectric layer is formed on the gate structure and the dummy gate structure, and a polishing technique is performed to planarize the upper surfaces of the dielectric layer, the gate structure and the dummy gate structure.

The method 2 is merely an example, and is not intended to limit the present disclosure beyond what is explicitly recited in the claims. Additional operations can be provided before, during, and after the method 2, and some operations described can be replaced, eliminated, or reordered for additional embodiments of the method.

Some embodiments of the present disclosure provide a semiconductor device. The semiconductor device includes a substrate, a gate electrode, a first doped region, a second doped region, and a dummy gate electrode. The gate electrode is disposed on the substrate. The first doped region and the second doped region are disposed on two opposite sides of the gate electrode. The dummy gate electrode is disposed on the substrate and between the gate electrode and the second doped region.

Some embodiments of the present disclosure provide a semiconductor device. The semiconductor device includes an insulating structure, a gate electrode, a source feature and a drain feature, and a dummy gate electrode. The insulating structure is within a substrate. The gate electrode is disposed on the insulating structure. The source feature and the drain feature are disposed on two opposite sides of the gate structure. A distance between the gate electrode and the source feature is different from a distance between the gate electrode and the drain feature. The dummy gate structure is disposed on the insulating structure.

Some embodiments of the present disclosure provide a method of manufacturing a semiconductor device. The method includes providing a substrate. The method also including forming a gate electrode and a dummy gate electrode on the substrate. The method further includes forming a first doped region abutting the gate electrode and a second doped region abutting the dummy gate electrode.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a gate electrode disposed on the substrate;
a first doped region and a second doped region disposed on two sides of the gate electrode; and
a dummy gate electrode disposed on the substrate and between the gate electrode and the second doped region.

2. The semiconductor device of claim 1, further comprising:
a cap layer disposed on the dummy gate electrode.

3. The semiconductor device of claim 1, wherein a distance between the gate electrode and the first doped region is different from a distance between the gate electrode and the second doped region.

4. The semiconductor device of claim 1, further comprising:
an insulating structure at least within the substrate, wherein the gate electrode is disposed on the insulating structure.

5. The semiconductor device of claim 4, wherein the dummy gate electrode is disposed on the insulating structure.

6. The semiconductor device of claim 1, wherein a material of the dummy gate electrode comprises polysilicon, metal, or a combination thereof.

7. The semiconductor device of claim 6, wherein the dummy gate electrode is electrically floating.

8. The semiconductor device of claim 1, wherein a width of the dummy gate electrode is different from a width of the gate electrode.

9. The semiconductor device of claim 1, wherein an upper surface of the gate electrode is at an elevation different from an elevation of an upper surface of the dummy gate electrode with respect to the substrate.

10. A semiconductor device, comprising:
an insulating structure within a substrate;
a gate electrode disposed on the insulating structure;
a source feature and a drain feature disposed on two sides of the gate electrode, wherein a distance between the gate electrode and the source feature is different from a distance between the gate electrode and the drain feature; and
a dummy gate electrode disposed on the insulating structure.

11. The semiconductor device of claim 10, further comprising:
a dummy gate dielectric supporting the dummy gate electrode.

12. The semiconductor device of claim 11, wherein an upper surface of the dummy gate electrode is recessed from an upper surface of the dummy gate dielectric.

13. The semiconductor device of claim 10, wherein the insulating structure functions as a part of a gate dielectric.

14. The semiconductor device of claim 10, further comprising:
a spacer disposed on a sidewall of the dummy gate electrode; and
an isolation region embedded within the substrate,
wherein the drain feature is disposed between the spacer and the isolation region.

15. The semiconductor device of claim 10, further comprising:
a cap layer covering the dummy gate electrode.

16. A method of manufacturing a semiconductor device, comprising:
providing a substrate;
forming a gate electrode and a dummy gate electrode on the substrate; and
forming a first doped region abutting the gate electrode and a second doped region abutting the dummy gate electrode.

17. The method of claim 16, further comprising:
forming an insulating structure within the substrate,
wherein the gate electrode and the dummy gate electrode are formed on the insulating structure.

18. The method of claim 16, wherein forming the gate electrode and the dummy gate electrode comprises:
forming a first sacrifice gate and a second sacrifice gate on the substrate;
forming a dielectric layer surrounding the first sacrifice gate and the second sacrifice gate;
removing the first sacrifice gate and the second sacrifice gate to form a first opening and a second opening; and
forming the gate electrode within the first opening and the dummy gate electrode within the second opening.

19. The method of claim 16, further comprising:
removing a portion of the dummy gate electrode; and
forming a cap layer on the dummy gate electrode.

20. The method of claim 16, wherein forming the first doped region and the second doped region comprises:
forming an isolation region within the substrate;
forming a first sacrifice gate and a second sacrifice gate on the substrate;
forming a first spacer on the first sacrifice gate and a second spacer on the second sacrifice gate;
doping impurities into the substrate to form the first doped region between the isolation region and the first spacer and the second doped region between the isolation region and the second spacer; and
replacing the first sacrifice gate and the second sacrifice gate with the gate electrode and the dummy gate electrode.
